(19) United States
(12) Patent Application Publication
(10) Pub. No.: US 2022/0397594 A1
(43) Pub. Date: Dec. 15, 2022

(54) CAPACITIVE INTELLIGENT WORKSTATION DETECTION SYSTEM

(71) Applicant: ESPRESSIF SYSTEMS (SHANGHAI) CO., LTD., Shanghai (CN)

(72) Inventors: Yu XIONG, Shanghai (CN); Zhaocheng ZHAN, Shanghai (CN)

(21) Appl. No.: 17/769,994

(22) PCT Filed: Oct. 16, 2020
(86) PCT No.: PCT/CN2020/121633

§ 371 Date: Apr. 18, 2022

(30) Foreign Application Priority Data
Oct. 18, 2019 (CN) 201910993906.0

(51) Int. Cl. G01R 27/26; G01R 31/302

(52) U.S. Cl. CPC G01R 27/2605; G01R 31/3025

(57) ABSTRACT

A capacitive intelligent workstation detection system, comprising a capacitance detection sensor (1), a capacitive sensing module (201), a microprocessor module (202), a remote management platform (3) and a mobile APP, the capacitance detection sensor (1) detecting a capacitance change when a human body approaches, and after being processed by the capacitive sensing module (201), the capacitance change being sent to the microprocessor module (202) to form workstation state data, the workstation state data being sent to the remote management platform (3), and the remote management platform (3) processing the workstation state data, so as to obtain user habit data. A user uses the mobile APP to obtain relevant data by means of the remote management platform (3), and sends debugging and control information to a workstation detection device (2). The system uses the capacitive sensing module (201), has a small volume, a good concealment, a beautiful appearance and a flexible design, does not require complex optical and microwave devices and has no mechanical device, is less vulnerable to aging and abrasion, and has a long service life and good consistency. The remote management platform (3) serves as a data management and control center, and the mobile APP provides man-machine bidirectional interaction, so as to implement office electric appliance linkage energy-saving management and personnel management.

### TECHNICAL FIELD

The disclosure relates to the technical field of workstation detection, in particular to a capacitive intelligent workstation detection system.

### BACKGROUND ART

With the tightening of enterprise office resources and the increasing of requirements for refined personnel management as well as energy conservation and environmental protection, the on-site detection of staffs and the energy-saving management of office appliances has gradually become more refined and intelligent.

The Chinese patent application “Intelligent Guest Chair and Guest Chair System for Collecting Data” (Publication No. CN109981799A) discloses an intelligent guest chair and a guest chair system for collecting data, where the guest chair comprises a guest chair body, an electronic module, a ZigBee networking configuration button, with the electronic module arranged in the guest chair body and the ZigBee networking configuration button arranged on the upper surface of the guest chair body and correspondingly connected with the electronic module; the intelligent guest chair of the application senses whether the customer is using the guest chair via the ZigBee networking configuration button, thereby obtaining the customer in-store information.

The Chinese utility model patent “Library Seat Management System” (CN208432884U) discloses a library seat management system, which uses seats equipped with pyroelectric sensors or pressure sensors to monitor whether the library seats are free.

The detection of these workstations or seats generally adopts pyroelectric infrared sensors, microwave sensors, mechanical buttons, etc., however, these approaches have many defects:

Firstly, due to the complex electromagnetic environment, frequent personnel exchanges, interference of ambient temperature and humidity, and sensor detection angles in the offices, the detection reliability is low, which cannot meet the needs of stable and refined management.

Secondly, traditional workstation detection devices require long-term power supply due to the high power consumption, leading to safety risks such as leakage of electricity. Thirdly, traditional workstation detection devices still have such disadvantages as large size, unsightly appearance, extensive wiring, high power consumption and poor concealment, which makes the office intelligent transformation difficult and the office environment uncomfortable.

Finally, traditional workstation detection devices require a large number of discrete elements and special housing materials, resulting in high unit cost, poor consistency, complicated production, and complicated installation and commissioning. As a result, the procurement cost of the enterprise is high, and it requires arranging personnel for installation and commissioning as well as periodic maintenance.

### SUMMARY OF THE INVENTION

An object of the disclosure is to provide a workstation detection system with high reliability, short installation and commissioning time, low production and maintenance costs, and easy management, which mainly solves the above problems existing in the prior art. In order to achieve the above object, the technical solution adopted in the disclosure is to provide a capacitive intelligent workstation detection system, comprising a capacitive detection sensor, a workstation detection device, a remote management platform, and a mobile APP; the workstation detection device comprises a lithium battery power supply module, a capacitive sensing module, a wireless transmission module, and a microprocessor module; the lithium battery power supply module provides operating power for the capacitive sensing module, the wireless transmission module, and the microprocessor module;

the capacitance detection sensor produces a capacitance change when a human body approaches, and after being processed by the capacitive sensing module, the capacitance change is passed to the microprocessor module for detection to complete human body identification and generate workstation state data; the microprocessor module sends the workstation state data to the remote management platform through the wireless transmission module; and the remote management platform receives, processes, and saves the workstation state data from the workstation detection device, generates and saves user habit information by utilizing historical workstation state data, and provides feedback to the user through the mobile APP.

Further, the capacitance detection sensor comprises an insulating cover layer, a parallel plate electrode, and an insulating substrate; the capacitive sensing module comprises a signal conditioning circuit; the signal conditioning circuit periodically charges and discharges the capacitance detection sensor, and outputs a number of pulses to the microprocessor module based on the capacitance value reported by the capacitance detection sensor; the microprocessor module performs calculations on the capacitance change outputted by the capacitive sensing module through digital filtering to obtain the workstation state data. Further, when a change of the workstation state data within L minutes does not exceed a threshold, the microprocessor module enters a sleep mode after finishing communication with the remote management platform;

The capacitive sensing module comprises an interruption module, when the number of pulses outputted by the capacitive sensing module reaches the threshold, the interruption module sends an interruption signal to the microprocessor; when the microprocessor module receives the interruption signal when in the sleep mode, it enters a normal operating mode.

Further, the microprocessor module comprises a timer, and the timer sends an interruption signal to the microprocessor module every M hours; after receiving the interruption signal from the timer, the microprocessor module sends a heartbeat packet to the remote management platform;

If the microprocessor module receives the interruption signal when in the sleep mode, it first enters the normal operating mode, and then sends the heartbeat packet to the remote management platform;

The remote management platform monitors the workstation state data and the heartbeat packet from the workstation detection system, and if any of the workstation state data or the heartbeat packet has not been received in M hours continuously, it determines that the workstation detection system is in an abnormal state.

Further, the remote management platform comprises a data processing center and a database; the data processing center performs receiving and processing of the workstation state data, and stores the workstation state data and the user habit information in the database.

Further, the lithium battery power supply module comprises a lithium battery charge and discharge management module, a buck-boost module, and a low power consumption power management module;

The wireless transmission module is a 2.4G wireless transmission module including a 2.4G antenna, a 2.4G filtering module, a wireless power amplification module, and a wireless modulation and demodulation module.

Further, the microprocessor module also comprises an electric power detection module; when the microprocessor module detects abnormal workstation state data, or detects low electric power state of the workstation detection device via the electric power detection module, it reports the abnormal state to the remote management platform; the remote management platform reminds the user of the abnormal state via the mobile APP or a background work order system.

Further, the user utilizes the mobile APP to set commissioning information or control information, and sends the information to the workstation detection device through the remote management platform for remote commissioning and management; after receiving the commissioning information or the control information, the workstation detection device executes the commissioning information or the control information.

Further, the workstation detection device also comprises a temperature and humidity sensor; the remote management platform sends the user habit information every N hours; the workstation detection device saves the user habit information, receives the temperature and humidity information collected by the temperature and humidity sensor, and generates calibration information by combining the user habit information, so as to adjust at least a parameter of the capacitive sensing module.

Further, when a change of the workstation state data within L minutes does not exceed the threshold, the microprocessor module enters a sleep mode after finishing communication with the remote management platform; when the wireless transmission module receives commissioning information or the control information, it sends a wake-up signal to the microprocessor; when the microprocessor module receives the wake-up signal when in the sleep mode, it enters the normal operating mode.

The disclosure introduces capacitive sensing technology, utilizes capacitance charge and discharge, parasitic capacitance principle, small signal conditioning, filtering technology, and adaptive calibration technology to provide workstation detection of high-reliability, and detects and analyzes various states and scenarios of the workstation to obtain accurate workstation state information, which can provide low power consumption and high reliability, one detection device for multiple workstations, and reduced on-site wiring due to wireless workstation state data transmission, solving the problems of traditional detection approaches, such as complex wiring, touch by mistake, huge size, vulnerability to ambient temperature and humidity interference, and high cost.

In view of the above technical features, the disclosure has the following advantages:

1. Low cost: the capacitive sensing module, 2.4G wireless transmission module, and microprocessor module are integrated SOC chips, which reduce the volume of the device volume and save the cost of peripheral circuits. The capacitive sensing module does not require complex optical and microwave components, and can detect changes in capacitance value simply using a PCB/FPC flexible electrode. It contains no mechanical device and is not prone to aging and wear, thereby having a long service life and good consistency. A single device can provide multiple detection channels, and the microprocessor module processes the multiple channels to realize one detection device for multiple workstations, further reducing the cost of workstation detection.

2. Powerful function: the mobile APP provides man-machine two-way interaction through the server as a data management and control center. The interconnected energy-saving management of office appliances and personnel management may be realized.

3. Easy installation: The small size, good concealment, aesthetic appearance and flexible design can avoid from being obtrusive in the office environment. The size and shape of the electrode of the capacitive sensing module can be adjusted to adapt to different object surfaces. The difficulty of installation and commissioning may be reduced. The 2.4G wireless transmission module may send and receive data using wireless technology without the need for wiring.

4. Low power consumption: Through the technologies such as capacitive sensing module wake-up and microprocessor module low power consumption management, long-term low-voltage and low-current power supply of lithium battery is realized, thereby electric power conservation and green office are achieved.

### BRIEF DESCRIPTION OF THE DRAWINGS

FIG. 1 is a schematic view of the components of each module of a preferred embodiment of the disclosure; and

FIG. 2 is a flow chart of workstation detection of a preferred embodiment of the disclosure.

In the drawings: 1—capacitance detection sensor, 2—workstation detection device, 3—remote management platform;

101—insulating cover layer, 102—parallel plate electrode, 103—insulating substrate; and

201—capacitive sensing module, 202—microprocessor module, 203—2.4G wireless transmission module, 204—lithium battery power supply module.

### DETAILED DESCRIPTION OF THE PREFERRED EMBODIMENTS

The disclosure will be further described below with reference to particular embodiments. It should be understood that these embodiments are only used to illustrate the disclosure and not intended to limit the scope of the disclosure. In addition, it should be understood that after reading the content taught in the disclosure, those skilled in the art can make various changes or modifications to the disclosure, and these equivalent forms fall within the scope set forth in the appended claims of the disclosure as well.

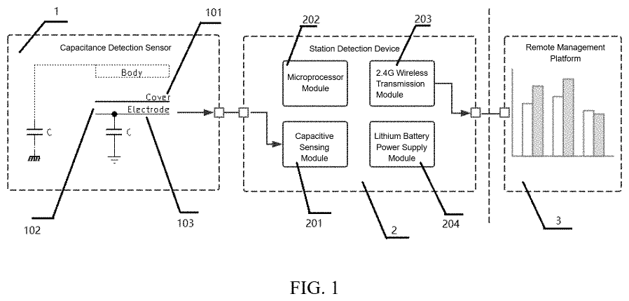

Please refer to FIG. 1, an intelligent workstation detection system of the disclosure comprises a capacitance detection sensor 1, a workstation detection device 2, a remote management platform 3, and a mobile APP. The workstation detection device 2 comprises a capacitive sensing module 201, a microprocessor module 202, a 2.4G wireless transmission module 203 and a lithium battery power supply module 204.

Among them, the capacitance detection sensor 1 consists of an insulating cover layer 101, a parallel plate electrode 102, and an insulating substrate 103. When a human body approaches the insulating cover layer 101 above the parallel plate electrode 102, the capacitance of the parallel plate electrode 102 varies depending on the two situations of being contacted (high capacitance) and non-contacted (low capacitance). The capacitive sensing module 201 comprises a signal conditioning circuit which periodically charges and discharges the capacitance detection sensor 1. When the capacitance value of the capacitance detection sensor 1 changes, the voltage change rate on the parallel plate electrode 102 in the capacitance detection sensor 1 also changes. The signal conditioning circuit modulates the voltage change rate into the number of output pulses, which is sent to the microprocessor module 2, and meanwhile an interruption signal is sent to the microprocessor module 2. The microprocessor module 2 filters the pulses and calculates the workstation state data.

The 2.4G wireless transmission module 203 is a wireless physical layer data transmission device, including a 2.4G antenna, a 2.4G filter module, a wireless power amplification module, and a wireless modulation and demodulation module. The lithium battery power supply module 204 comprises a lithium battery charge and discharge management module, a buck-boost module, and a low power consumption power management module, providing operating power for other modules in the system. The output ends of the lithium battery power supply module 204 are respectively connected to the capacitive sensing module 201, the microprocessor module 202, and the 2.4G wireless transmission module 203.

The output end of the capacitive sensing module 201 is connected to the microprocessor module 202, providing interruption wake-up and the capacitance value of the parallel plate electrode 102; the input and output ends of the microprocessor module 202 are connected to the 2.4G wireless transmission module 203, and the microprocessor module 202 processes the electrode capacitance value into workstation state data and modulated the data into link layer data to be sent through the 2.4G wireless transmission module 203. The microprocessor module 202 also receives control data and commissioning information from the 2.4G wireless transmission module 203, so that the workstation detection device 2 can be remotely commissioned and controlled. The 2.4G wireless transmission module 203 sends wake-up information to the microprocessor module 202 after receiving the control data and the commissioning information sent by the remote management platform 3.

The remote management platform 3 comprises a data processing center and a database; the data processing center receives and saves the workstation state data from the workstation detection device 2, processes the workstation state data to obtain the processed data such as user habit information, generates a series of data reports, further provides user interaction through the mobile APP, and can also realize the interconnected energy-saving management of office appliances and personnel management based on the accumulated user habits. The remote management platform 3 sends user habit information for the workstation detection device 2 to the workstation detection device 2 at a set interval (24 hours by default).

When the workstation state data detected by the workstation detection device 2 is abnormal (for example, the capacitance value exceeds the detection range) or a low power state, the workstation detection device 2 will report the abnormal state to the remote management platform 3 and remind the user or equipment manufacturer to handle the same through the mobile APP or a background work order system.

The user can generate commissioning information or control information through the mobile APP and send the same to the workstation detection device 2 through the remote management platform 3 for remote commissioning and management, such as reserving for on-off at a set time.

The microprocessor module 202 provides low power consumption function by providing switching between the sleep mode and the normal operating mode. After the microprocessor module 202 obtains the workstation state, it further ensures that the workstation state is consistent with the actual situation through an intelligent self-adaptive calibration algorithm, and automatically enters a sleep mode when the change is small within a workstation state data set time (1 minute by default). The sleep mode can be awakened by the interruption information sent by the capacitive sensing module 201, or awakened by the wake-up information sent by the 2.4G wireless transmission module 203, or awakened by the timer of the microprocessor module. In the normal operating mode, the microprocessor module 202 sends the workstation state data to a gateway through the 2.4G wireless transmission module 203, and the gateway forwards it to the remote management platform 3 to realize intelligent workstation state management, interconnected energy-saving management of office appliances, and reminder for being sedentary, etc.

The microprocessor module 202 also provides a heartbeat packet mechanism at the same time to ensure that the remote management platform 3 can monitor the normal operating mode of the microprocessor module 202. The microprocessor module 202 further comprises a timer, which is set to send interruption information to the microprocessor module 202 at regular intervals (24 hours by default). When the microprocessor module 202 receives the interruption information, if it is in the sleep mode, it is first awakened to enter the normal operating mode, and then sends the heartbeat packet information to the remote management platform 3. If the microprocessor module 202 is already in the normal operating mode when it receives the interruption information, it will directly send the heartbeat packet information. Meanwhile, the remote management platform 3 records the received information from the microprocessor module 202, including the workstation state data and the heartbeat packet data. If no workstation state data or heartbeat packet data is received within the set time (consistent with the time of the timer, 24 hours by default), it is considered that the workstation detection device 2 corresponding to the microprocessor module 202 is in abnormal state (power down or fault).

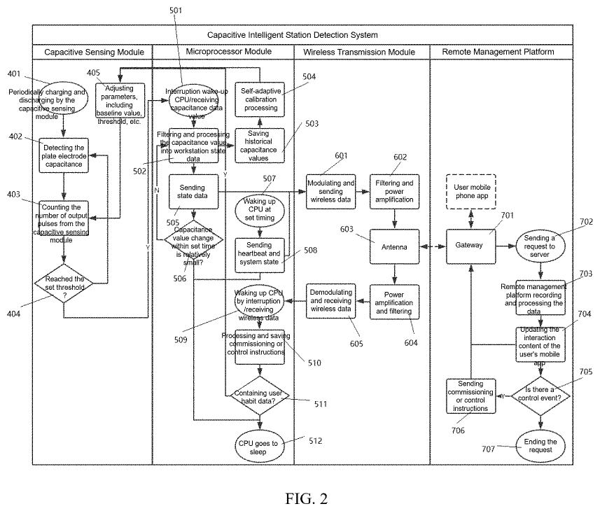

Please refer to FIG. 2, the operating process of the capacitive workstation detection system comprises the process of the capacitive sensing module, the process of the microprocessor module, the process of the wireless transmission module, and the process of the remote management platform.

The process of the capacitive sensing module includes the following steps:

Step 401) the signal conditioning circuit module of the capacitive sensing module periodically charges and discharges the parallel plate electrode, and detects the voltage.

Step 402) when the capacitance of the parallel plate electrode of the capacitance detection sensor changes, the signal conditioning circuit module detects the voltage change rate and outputs pulses.

Step 403) the capacitive sensing module counts the number of received pulses within a fixed time interval.

Step 404) when the number of pulses in the fixed time interval reaches a threshold set by the user in advance, sending an interruption to the microprocessor, and proceeding to (steps of the microprocessor) step 501, otherwise returning to step 402.

Step 405) adjusting the parameters of the capacitive sensing module to ensure the reliability of the device.

The process of the microprocessor module comprises the following steps:

Step 501) after the microprocessor module receives the interruption information from the capacitive sensing module, if the microprocessor module is in the sleep mode, it is awakened and enters a normal operating mode after receiving the interruption.

Step 502) the microprocessor module in normal operating mode obtains the capacitance change outputted by the capacitive sensing module through digital filtering, and further calculates the workstation state data.

Step 503) the microprocessor module saves the current capacitance value as historical capacitance data.

Step 504) the microprocessor module performs self-adaptive calibration based on the historical capacitance data and the temperature and humidity data of the working environment, and calculates the parameters of the capacitive sensing module such as the appropriate baseline value and threshold value, jumping to step 405 for execution, and proceeding to step 505 after the execution is completed.

Step 505) the microprocessor module jumps to (process steps of the wireless transmission module) step 601 to start executing the task of sending workstation state data, and goes to step 506 after the execution is completed.

Step 506) the microprocessor module determines that if the capacitance change value is relatively small within the set time (1 minute by default), go to step 512, otherwise go to step 502.

Step 507) after the microprocessor module receives the interruption information of the timer, if the microprocessor module is in the sleep mode, it is awakened to enter normal operating mode after receiving the interrupt.

Step 508) the microprocessor module jumps to (process steps of the wireless transmission module) step 601 to start executing the task of sending the heartbeat packet, and goes to step 512 after the execution is completed.

Step 509) after the microprocessor module receives the interruption information of the wireless transmission module, if the microprocessor module is in the sleep mode, it is awakened and enters a normal operating mode after receiving the interruption.

Step 510) the microprocessor module processes, and saves the commissioning information or control information, and executes the same.

Step 511) if the received commissioning information or control information contains user habit information, the microprocessor module calculates the calibration parameters of the capacitive sensing module based on the temperature and humidity data in the device, in combination with the user habit information sent by the remote management platform, turn to step 405 for execution, and go to step 512 after the execution is completed.

Step 512) the microprocessor module enters the sleep mode.

The process of the wireless transmission module process comprises two types of operations including sending and receiving, in which the sending process comprises the following steps:

Step 601) the wireless transmission module modulates the workstation state data.

Step 602) the wireless transmission module performs filtering and power amplification on the modulated signal.

Step 603) the wireless transmission module communicates with the remote management platform through the wireless antenna.

The process of the wireless transmission module process comprises two types of operations including sending and receiving, in which the receiving process comprises the following steps:

Step 603) the wireless transmission module communicates with the remote management platform through the wireless antenna.

Step 604) when the wireless antenna receives the signal from the remote platform, it performs power amplification and filtering on the signal.

Step 605) the wireless transmission module demodulates the signal, sends interruption information to the microprocessor, and proceeds to (steps of the microprocessor) step 509 to continue the processing. The receiving by the wireless transmission module is completed.

The process of remote management platform consists of the following steps:

Step 701) a gateway of the remote management platform receives signals, including the workstation state data and the heartbeat packet reported by the workstation detection system, and the interaction data of the mobile APP.

Step 702) the remote management platform sends a request to a server.

Step 703) the remote management platform receives and processes the heartbeat packet from the workstation detection device. The remote management platform receives and processes the workstation state data from the workstation detection device and saves the same to the database, and then generates and saves user habit information by utilizing the historical workstation state data.

Step 704) the remote management platform updates the interaction content of the mobile APP, and sends it to the mobile APP through the gateway. The mobile APP feeds back the processing results to the user. The user may also set commissioning information or control information by using the mobile APP, and send it to the remote management platform through the gateway.

Step 705) the remote management platform detects the information returned by the mobile APP, and when no commissioning information or control information is found, go to step 707, otherwise go to step 706.

Step 706) sending commissioning information or control information to the workstation detection device through the gateway.

Step 707) the processing of the remote management platform is completed.

The above description describes only preferred embodiments of the disclosure, and is not intended to limit the scope of the disclosure. Any equivalent structure or equivalent process variants made by utilizing the contents of the description and drawings of the disclosure, or directly or indirectly applied to other related technical fields, are similarly included in the scope of patent protection of the disclosure.

1. A capacitive intelligent workstation detection system, comprising a capacitive detection sensor, a workstation detection device, a remote management platform, and a mobile APP, wherein the workstation detection device comprises a lithium battery power supply module, a capacitive sensing module, a wireless transmission module, and a microprocessor module; the lithium battery power supply module provides operating power for the capacitive sensing module, the wireless transmission module, and the microprocessor module;
the capacitance detection sensor produces a capacitance change when a human body approaches, and after being processed by the capacitive sensing module, the capacitance change is passed to the microprocessor module for detection to complete human body identification and generate workstation state data; the microprocessor module sends the workstation state data to the remote management platform through the wireless transmission module;
the remote management platform receives, processes, and saves the workstation state data from the workstation detection device, generates and saves user habit information by utilizing historical workstation state data, and provides feedback to a user through the mobile APP.

2. An intelligent workstation detection system of claim 1, wherein the capacitance detection sensor comprises an insulating cover layer, a parallel plate electrode, and an insulating substrate; the capacitive sensing module comprises a signal conditioning circuit, wherein the signal conditioning circuit periodically charges and discharges the capacitance detection sensor, and outputs a number of pulses to the microprocessor module based on a capacitance value reported by the capacitance detection sensor; the microprocessor module performs calculations on the capacitance change outputted by the capacitive sensing module through digital filtering to obtain the workstation state data.

3. An intelligent workstation detection system of claim 2, wherein when a change of the workstation state data within L minutes does not exceed a threshold, the microprocessor module enters a sleep mode after finishing communication with the remote management platform; and
the capacitive sensing module comprises an interruption module, when the number of pulses outputted by the capacitive sensing module reaches the threshold, the interruption module sends an interruption signal to the microprocessor; when the microprocessor module is in the sleep mode and receives the interruption signal, the microprocessor module enters a normal operating mode.

4. An intelligent workstation detection system of claim 1, wherein the microprocessor module comprises a timer, and the timer sends an interruption signal to the microprocessor module every M hours; after receiving the interruption signal from the timer, the microprocessor module sends a heartbeat packet to the remote management platform;
if the microprocessor module receives the interruption signal when in the sleep mode, the microprocessor module enters the normal operating mode, and then sends the heartbeat packet to the remote management platform; and
the remote management platform monitors the workstation state data and the heartbeat packet from the workstation detection system, and if any of the workstation state data or the heartbeat packet has not been received in M hours continuously, the remote management platform determines that the workstation detection system is in an abnormal state.

5. An intelligent workstation detection system of claim 1, wherein the remote management platform comprises a data processing center and a database, wherein the data processing center performs receiving and processing of the workstation state data, and stores the workstation state data and the user habit information in the database.

6. An intelligent workstation detection system of claim 1, wherein the lithium battery power supply module comprises a lithium battery charge and discharge management module, a buck-boost module, and a low power consumption power management module; and
the wireless transmission module is a 2.4G wireless transmission module including a 2.4G antenna, a 2.4G filtering module, a wireless power amplification module, and a wireless modulation and demodulation module.

7. An intelligent workstation detection system of claim 1, wherein the microprocessor module further comprises an electric power detection module; when the microprocessor module detects abnormal workstation state data, or detects a low electric power state of the workstation detection device via the electric power detection module, the microprocessor module reports the abnormal state to the remote management platform; the remote management platform reminds the user of the abnormal state via the mobile APP or a background work order system.

8. An intelligent workstation detection system of claim 1, wherein the user utilizes the mobile APP to set commissioning information or control information, and sends the information to the workstation detection device through the remote management platform for remote commissioning and management; after receiving the commissioning information or the control information, the workstation detection device executes the commissioning information or the control information.

9. An intelligent workstation detection system of claim 8, wherein the workstation detection device also comprises a temperature and humidity sensor; the remote management platform sends the user habit information every N hours; the workstation detection device saves the user habit information, receives the temperature and humidity information collected by the temperature and humidity sensor, and generates calibration information based on the user habit information, so as to adjust at least a parameter of the capacitive sensing module.

10. The intelligent workstation detection system of claim 8, wherein when the change of the workstation state data within L minutes does not exceed the threshold, the microprocessor module enters a sleep mode after finishing communication with the remote management platform; when the wireless transmission module receives commissioning information or the control information, the wireless transmission module sends a wake-up signal to the microprocessor; when the microprocessor module receives the wake-up signal when in the sleep mode, the microprocessor module enters the normal operating mode.
